(19) United States
(12) Patent Application Publication
(10) Pub. No.: US 2025/0159987 A1
(43) Pub. Date: May 15, 2025

(54) RF FRONT-END CHIP, MANUFACTURING METHOD THEREOF, CIRCUIT STRUCTURE AND RF COMMUNICATION DEVICE

(71) Applicant: Hangzhou Geo-chip Technology Co., Ltd., Hangzhou (CN)

(72) Inventor: Ruili WU, Hangzhou (CN)

(21) Appl. No.: 18/794,001

(22) Filed: Aug. 5, 2024

(30) Foreign Application Priority Data
Nov. 9, 2023 (CN) 202311488549.5

(51) Int. Cl. H01L 27/12; H01L 21/84; H01L 23/00; H01L 23/66; H03F 1/56; H03F 3/24

(52) U.S. Cl. CPC H10D 86/201; H01L 23/66; H01L 24/16; H03F 1/56; H03F 3/245; H10D 86/01; H01L 2223/665; H01L 2223/6655; H01L 2224/16225; H01L 2924/10329; H01L 2924/1421; H01L 2924/15313; H03F 2200/451

(57) ABSTRACT

The present disclosure provides a radio frequency (RF) front-end chip, a circuit structure and an RF communication apparatus, where the RF front-end chip includes at least one substrate, and an RF power amplifier (PA) chip integrating therein based on a CMOS process at least an RF PA circuit, a control logic circuit, and optionally a switching circuit, where the RF PA chip is mounted on the at least one substrate based on a SOI process. With the above chip, chip integration can be improved at a low cost.

### CROSS REFERENCES TO RELATED APPLICATIONS

This application claims priority to Chinese Patent Application No. 202311488549.5, filed on Nov. 9, 2023 and entitled “RF FRONT-END CHIP, MANUFACTURING METHOD THEREOF, CIRCUIT STRUCTURE AND RF COMMUNICATION APPARATUS”, which is incorporated by reference herein in its entirety.

### TECHNICAL FIELD

The present disclosure relates to the field of communications, and in particular relates to a radio frequency (RF) front-end chip, a manufacturing method thereof, a circuit structure and an RF communication apparatus.

### BACKGROUND

This section is intended to provide a background or context for the embodiments of the present disclosure as set forth in the claims. What is described herein is not admitted as the prior art merely by virtue of its inclusion in this section.

RF (radio frequency) chips, which are typically packaged using System in Package (SiP) technology, each include mainly an RF amplification circuit, a corresponding RF matching circuit and other components.

In current RF signal amplification modules, the power amplification effect and stability is improved typically by gallium arsenide (GaAs) chip solutions, among which a relatively typical configuration is that a bare die, a GaAs die and a Silicon-On-Insulator (SOI) die are arranged side by side on a substrate and secured by bonding. The bare die includes a pre-Complementary Metal-Oxide-Semiconductor (CMOS) power amplifier and the following CMOS switch, the GaAs die includes a post-GaAs power amplifier, and the SOI die provides the switch. In other words, in this configuration of separately integrating the amplification chip, the switch chip, and the control chip on the substrate, the function of the RF signal amplification is achieved by designing positions and connection relationships of the amplification chip, the switch chip, and the control chip.

However, especially as the expensive gallium arsenide (GaAs) material becomes the primary raw material for the third-generation semiconductor chips, the existing configuration of separately integrating the amplification chip, the switch chip and the control chip on the substrate causes the resultant RF signal amplification modules to be bulky and costly and have low integration.

In order to accommodate the trend towards miniaturization of electronic devices, it is necessary to propose an RF chip achieving higher integration with lower cost.

### SUMMARY

In view of the above-mentioned problems existing in the prior art, an RF front-end chip, a manufacturing method thereof, a circuit structure and an RF communication apparatus are proposed, in order to provide a low-cost and high-integration RF chip to solve the above-mentioned problems.

The present disclosure provides the following solutions.

In a first aspect, an RF front-end chip is provided and includes at least one substrate, and an RF power amplifier (PA) chip integrating therein based on a CMOS process at least an RF PA circuit, a control logic circuit, and optionally a switching circuit, where the RF PA chip is mounted on the at least one substrate based on a SOI process.

In an embodiment, the integrated RF PA circuit may be configured to implement multi-stage power amplification for the RF PA chip, and may be provided on the same die as the control logic circuit or on a different die separately from the control logic circuit.

In an embodiment, the RF front-end chip further includes a matching circuit including a circuit winding and a surface-mounted element, where the matching circuit is mounted on the substrate and is electrically connected to the RF PA chip to provide impedance matching.

In an embodiment, the switching circuit is arranged at the front end of or between stages of the multi-stage power amplification of the RF PA circuit, and is configured to perform switching between amplifier modules of different frequency bands in cooperation with the control logic circuit.

In an embodiment, the RF PA chip is implemented as a first die integrating therein the control logic circuit for supplying logic levels to the circuitry, the switching circuit and the RF PA circuit, where the RF PA chip is mounted on one substrate based on the SOI process.

In an embodiment, the RF PA chip is implemented by:
a second die integrating therein a bias circuit for supplying a bias voltage, the control logic circuit, and the RF PA circuit; and
a third die integrating therein the switching circuit,
where the second die and the third die are mounted on the same substrate based on the SOI process.

In an embodiment, the RF PA chip is implemented by:
a fourth die integrating therein the control logic circuit and the switching circuit; and
a fifth die integrating therein the RF PA circuit.

In an embodiment, the RF PA chip further includes a sixth die integrating therein the RF PA circuit and a control logic circuit for supplying logic levels to the circuitry.

In an embodiment, the RF PA chip is packaged through a flip-chip land grid array (FC-LGA) process onto the substrate using the SOI process.

In an embodiment, the RF PA circuit includes an amplifier module corresponding to a predetermined frequency band, and the switching circuit includes a sub-switching circuit corresponding to the predetermined frequency band, with the sub-switching circuit being integrated to the amplifier module.

In a second aspect, a circuit structure is provided, which includes the RF front-end chip of the first aspect.

In a third aspect, an RF communication apparatus is provided, which includes the RF front-end chip of the first aspect.

One of the advantages of the above-mentioned embodiments lies in that, by realizing the RF PA of the RF front-end completely by using a high-integration SOI CMOS process, i.e., achieving the amplification function of the RF front-end by using a CMOS integrated chip, a low-cost and highly integrated RF chip can be provided.

Other advantages of the present disclosure will be explained in more detail in conjunction with the following description and the accompanying drawings.

It should be understood that the above description is a summary of the technical solutions of the present disclosure only for the purpose of facilitating a better understanding of the technical means of the present disclosure so that the disclosure can be implemented according to the description in the specification. Specific embodiments of the present disclosure are given below to render the above and other objects, features and advantages of the present disclosure more clear.

### BRIEF DESCRIPTION OF DRAWINGS

Through reading the detailed description of the exemplary embodiments below, a person of ordinary skill in the art would understand the advantages and benefits described herein and other advantages and benefits. The drawings are only for the purpose of illustrating exemplary embodiments and are not intended to be limitations to the present disclosure. Moreover, the same reference characters are used throughout the drawings to represent the same components. In the drawings:

FIG. 1 is a schematic structural diagram showing an RF front-end chip according to one embodiment of the present disclosure;

FIG. 2(a) is another schematic structural diagram showing an RF front-end chip according to one embodiment of the present disclosure;

FIG. 2(b) is a schematic structural diagram showing an actual layout structure of an RF front-end chip according to one embodiment of the present disclosure;

FIG. 3(a) is a schematic structural diagram showing an RF front-end chip according to one embodiment of the present disclosure;

FIG. 3(b) is a schematic structural diagram showing an actual layout of an RF front-end chip according to one embodiment of the present disclosure;

FIG. 4 is another schematic structural diagram showing an RF front-end chip according to one embodiment of the present disclosure;

FIG. 5 is another schematic structural diagram showing an RF front-end chip according to one embodiment of the present disclosure;

FIG. 6 is another schematic structural diagram showing an RF front-end chip according to one embodiment of the present disclosure.

FIG. 7 is a schematic structural diagram showing an RF front-end chip according to one embodiment of the present disclosure;

FIG. 8 is a schematic structural diagram showing an RF front-end chip according to one embodiment of the present disclosure.

FIG. 9 is a schematic structural diagram showing a switching circuit of an RF front-end chip according to one embodiment of the present disclosure;

FIG. 10 is a schematic structural diagram showing flip-chip of an RF front-end chip according to one embodiment of the present disclosure.

In the drawings, the same or corresponding reference numerals denote the same or corresponding parts.

### DETAILED DESCRIPTION

The exemplary embodiments of the present disclosure will be described in more detail below with reference to the drawings. Although the exemplary embodiments of the present disclosure are shown in the drawings, it should be understood that the present disclosure can be implemented in various forms and should not be limited by the embodiments described herein. Rather, these embodiments are provided to facilitate more thorough understanding of the present disclosure, so that the scope of the disclosure could be fully conveyed to a person of ordinary skill in the art.

In the description of the embodiments of the present disclosure, it should be understood that terms such as “including” or “having” are intended to indicate the presence of features, numbers, steps, behaviors, components, parts, or combinations thereof disclosed in this specification, and are not intended to exclude the possibility of the presence of one or more other features, numbers, steps, behaviors, components, parts, or combinations thereof.

Unless otherwise specified, “/” refers to “or”. For example, A/B may indicate A or B. In this specification, the term “and/or” merely describes the association relationship between the associated objects and indicates that there may be three relationships. For example, A and/or B may indicate three cases where only A exists, both A and B exist, and only B exists.

The terms such as “first” and “second” are for descriptive purposes only and are not intended to be construed as indicating or implying a relative importance or implicitly indicating the number of technical features indicated. Hence, features defined by “first” or “second” may explicitly or implicitly include one or more features. In the description of the embodiments of the present disclosure, “a plurality of” means two or more in number, unless otherwise specified.

In addition, it should be noted that the embodiments and the features of the embodiments in the present disclosure can be combined with each other without conflict. The present disclosure will now be described in detail in connection with the embodiments with reference to the accompanying drawings.

The inventors have found that the current way of forming the RF front-end chip by using the CMOS process combined with the GaAs process would cause the RF front-end chip to be bulky and less integrated, and the required GaAs-based devices will lead to high cost of the RF front-end chip.

In view of the above problems, the inventors has designed an RF front-end chip based on the SOI CMOS process.

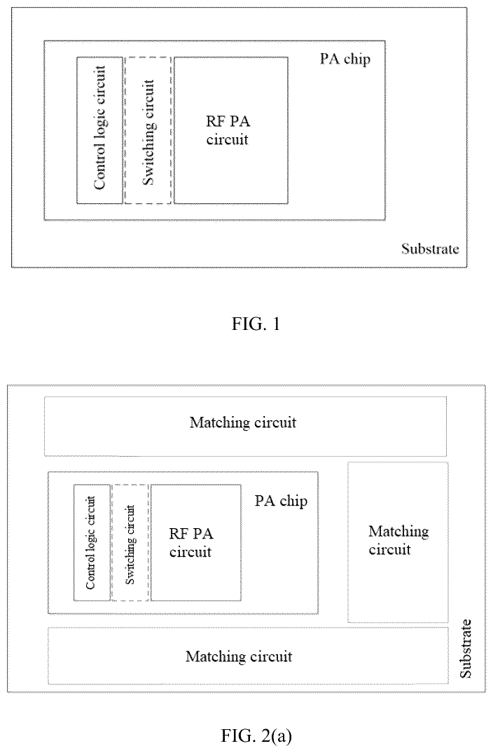

Referring to FIG. 1, the present disclosure provides an RF front-end chip, which includes at least one substrate, and an RF power amplifier (PA) chip integrating therein based on a CMOS process at least an RF PA circuit, a control logic circuit, and optionally a switching circuit, where the RF PA chip is mounted on the at least one substrate based on a SOI process.

The SOI process described above is a technology that introduces a buried oxide layer between the top silicon and a handle wafer (also referred to as the substrate).

The structural feature of the SOI CMOS process in the embodiments of the present disclosure is to provide a thicker oxide layer (such as silicon oxide), also referred to as a buried oxide layer, between the active region and the substrate (i.e., a silicon wafer) of the RF front-end chip. Thus, in a device manufactured by the SOI CMOS process, each active device is surrounded by an oxide layer and hence is completely isolated from the surrounding devices, thereby essentially eliminating the latch-up effect. Since a PN junction formed by the source, drain and substrate is prevented, the parasitic capacitance of the MOS transistor is reduced. The buried oxide layer also increases the thickness of the insulating layer between the interconnection line and the substrate, thereby greatly reducing the parasitic capacitance of the interconnection line. Reducing the capacitance is beneficial to increase the speed and reduce the power consumption of the circuit.

SOI process, i.e., in other words, a full SOI CMOS process, may be used in certain embodiments of the present disclosure, and thus the power amplification function at the RF front end is realized with fewer devices and higher integration. In other words, the RF PA chip may be mounted on the at least one substrate completely based on the SOI process. However, the present disclosure does not exclude the possibility of further using any other known process for mounting the RF PA chip in combination with the SOI process.

In an embodiment, an RF PA circuit integrated in the RF PA chip may be configured to implement power amplification, and may be provided on the same one die as the control logic circuit or on a different die separately from the control logic circuit.

Specifically, the RF PA circuit generally includes multiple stages of amplification. Unlike the existing technical solutions of using different CMOS processes combined with gallium arsenide (GaAs) processes to respectively implement different stages of power amplification, the embodiment of the present disclosure uses a single SOI CMOS process to implement all the multiple stages of power amplification circuits.

In principles of implementation, a CMOS die integrates a Mobile Industry Processor Interface (MIPI) circuit and a bias circuit, in addition to a control logic circuit, a switch circuit and an RF PA circuit. In the present disclosure, the switch circuit is no longer located at the rear end of the RF amplifier, but is located at the front end of the RF amplifier or between amplifier (PA) stages. This in turn reduces the RF switch circuits, because of the overall circuit principle that an analog part of the die provides a bias for the RF PA circuit and the RF signals of different paths are switched at the front end of the RF amplifier or between amplifier stages, and then the final stage of the RF PA circuit is directly connected to the antenna port to transmit power.

Further, the RF PA circuit of the present embodiment may be provided on the same one die as the control logic circuit or on a different die separately from the control logic circuit, but in either case the die is implemented by the SOI CMOS process.

Further, the RF front-end chip further includes a matching circuit including a circuit winding and a surface-mounted element, where the matching circuit is mounted on the substrate and is electrically connected to the RF PA circuit to provide impedance matching.

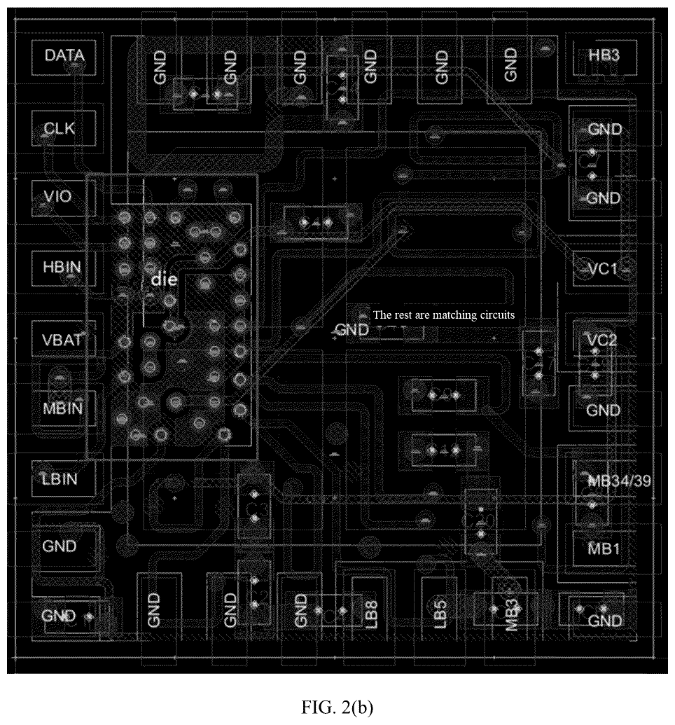

Referring to FIG. 2(a), a matching circuit disposed around the integrated RF PA chip is also mounted on the substrate, and is connected to an interface circuit of the RF PA chip.

Referring to FIG. 2(b) which shows a physical structure implementing the circuit of FIG. 2(a), an integrated RF PA chip is integrated on a die surrounded by matching circuits, the matching circuits being connected to the interface circuits of the RF PA chip.

In an embodiment, the switching circuit is arranged at the front end of the multiple stages of power amplification of the RF PA circuit or between these stages, and is configured to perform switching between amplifier modules of different frequency bands in cooperation with the control logic circuit.

As previously mentioned, the RF PA circuit typically includes multiple stages of amplification, and the switching circuit of embodiments of the present disclosure is no longer located at the rear end of the RF PA circuit, but instead is located at the front end of the RF PA circuit or between amplifier stages of the RF PA circuit, e.g., in front of the front amplifier stage, between the front amplifier stage and the intermediate amplifier stage, between the intermediate amplifier stage and the last amplifier stage, and so on, which in turn reduces the switching circuits.

Furthermore, the overall circuit principle of the embodiments of the present disclosure is that an analogue part of the die provides a bias for an RF PA circuit and RF signals of different paths are switched between amplifier stages, and then the final stage of the RF PA circuit is directly connected to an RF power transmitting antenna to transmit the amplified power.

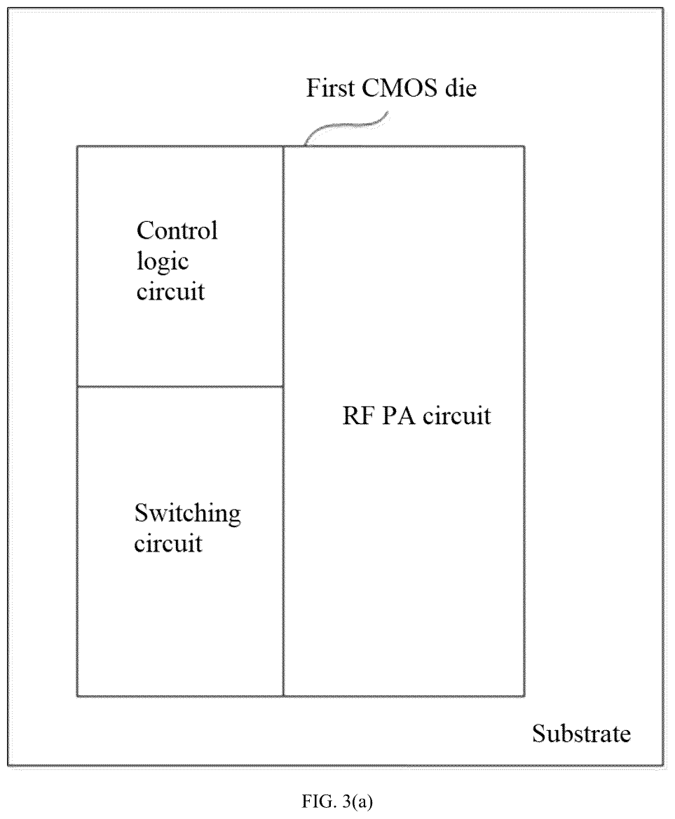

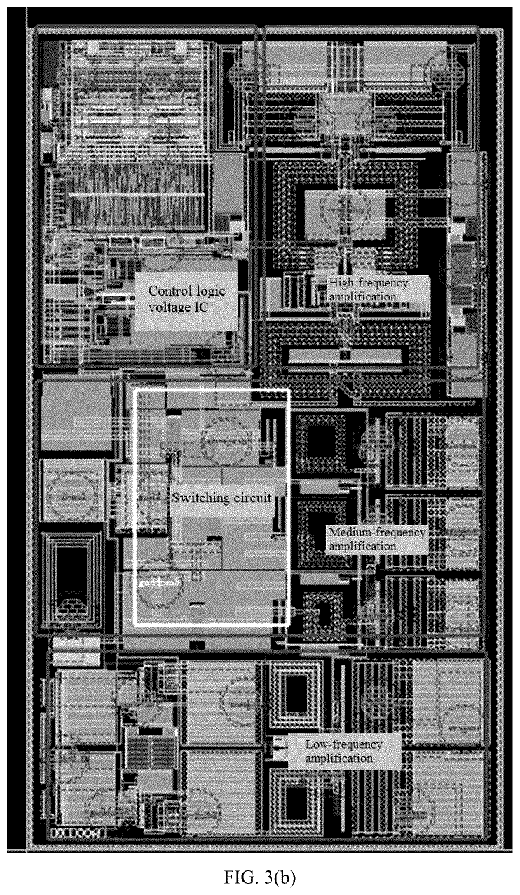

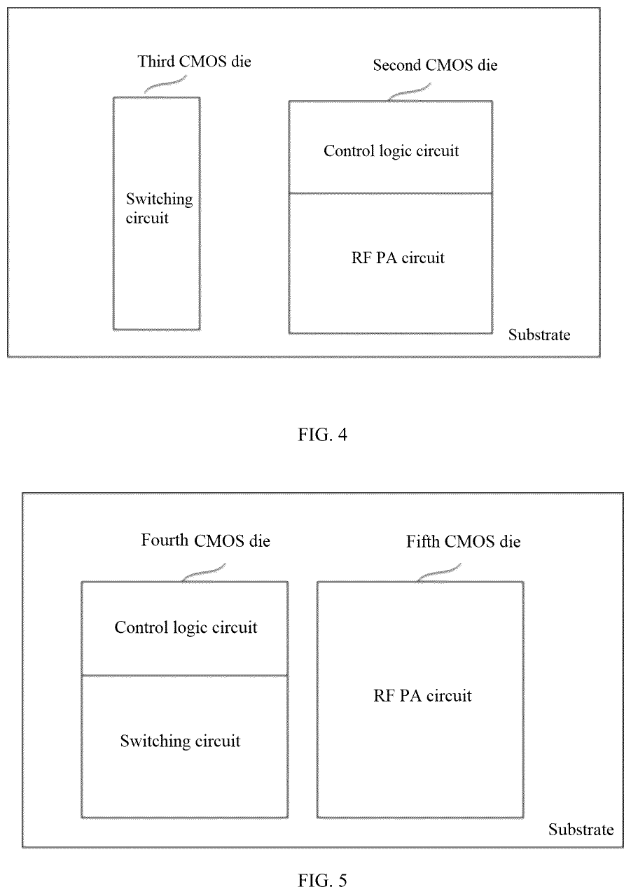

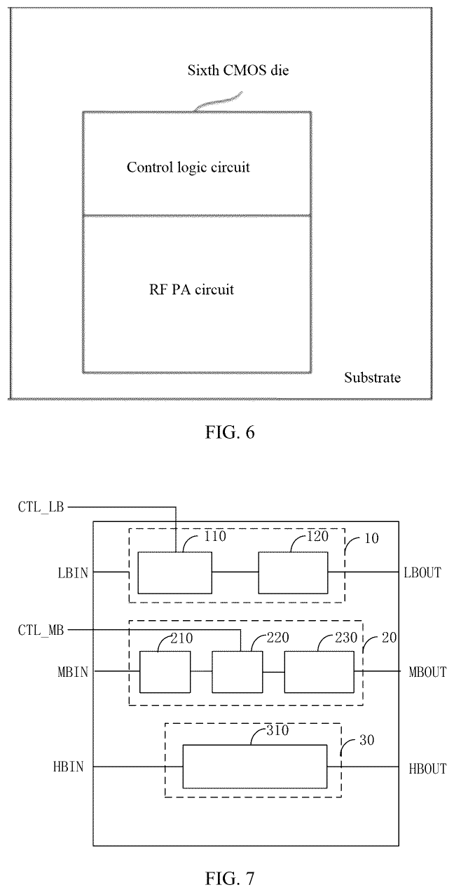

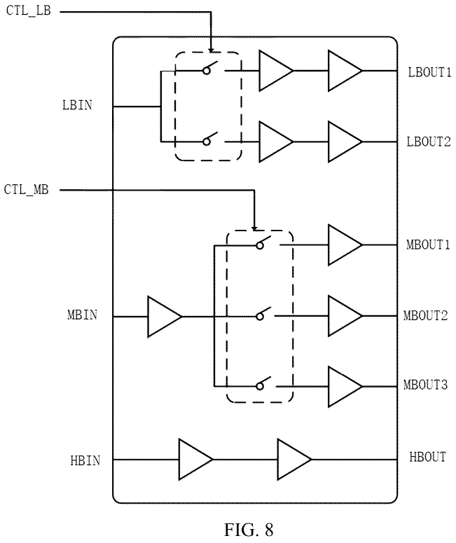

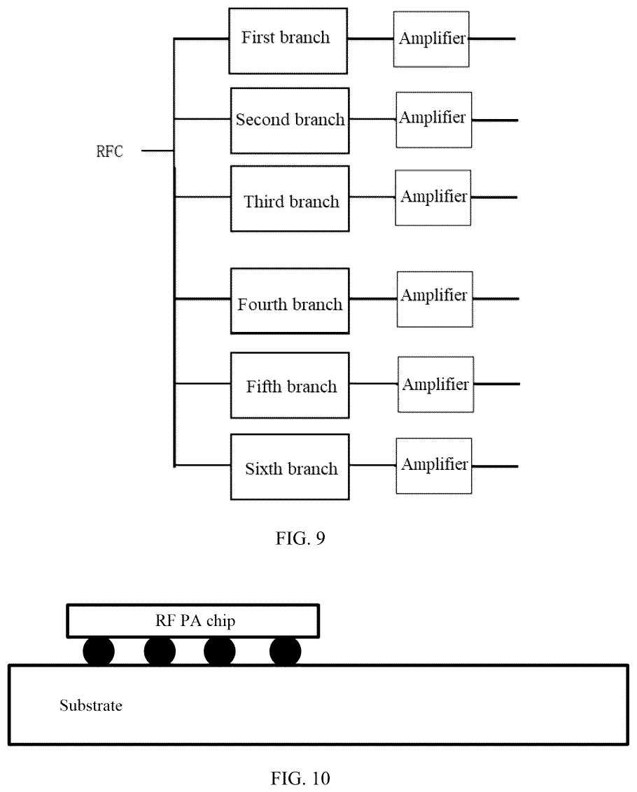

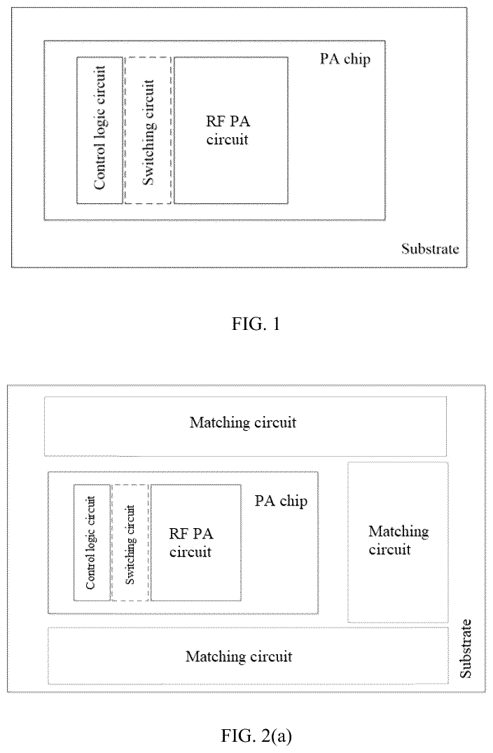

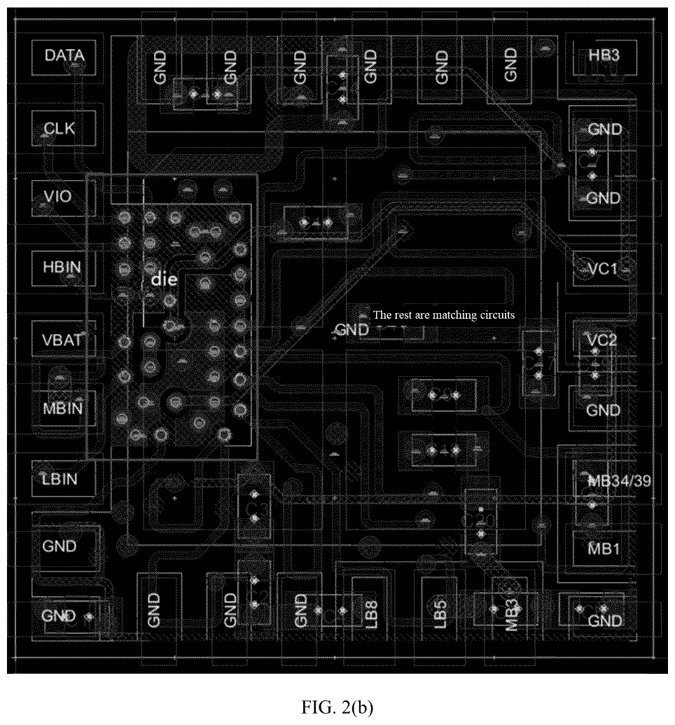

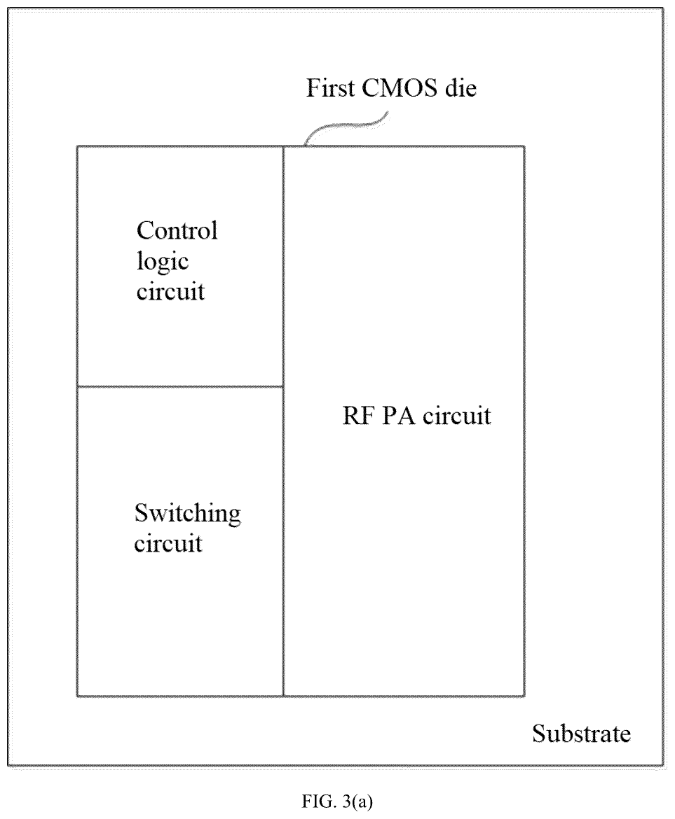

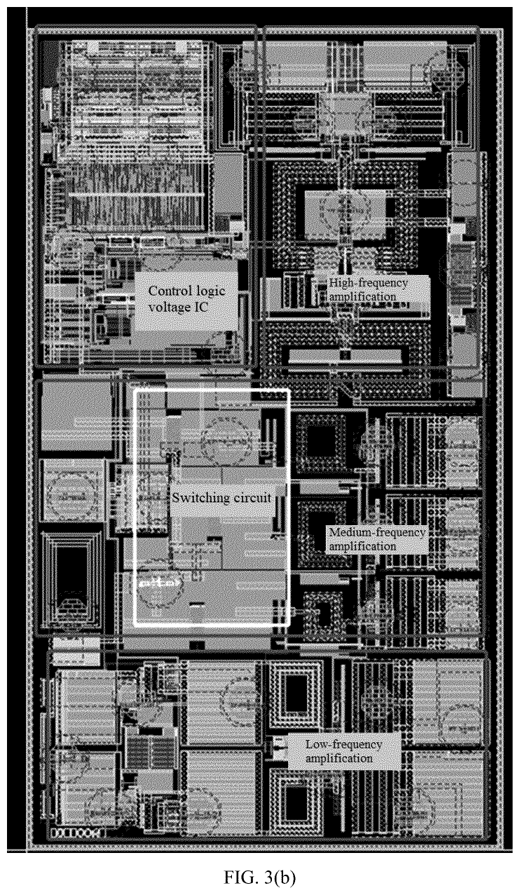

Referring to FIG. 3(a), in an embodiment, the RF PA chip may be implemented by using one die to achieve a fully integrated CMOS PA chip, and mounted on one substrate based on the full SOI process.

Specifically, the RF PA chip includes a first die integrating therein the control logic circuit for providing logic levels to the circuitry, the switching circuit and the RF PA circuit; and the MIPI circuit (not shown in the figure) and a bias circuit (not shown in the figure) for providing a bias voltage for the whole circuitry can also be integrated thereto.

In other words, the control logic circuit (CTRL), the RF PA circuit (PA), and the switching circuit (SW) are all integrated on the first die.

Herein, the switching circuits are connected between stages of the multi-stage power amplification circuit of the RF PA circuit, that is, the switching circuits are embedded into the RF PA circuit but are not formed as a separate circuit structure, thereby reducing the switching circuits. Furthermore, the switching circuit can cooperate with the control logic circuit to switch amplifier modules of different frequency bands, and a rear end of the RF amplifier circuit is connected to an RF transmitting antenna to directly transmit the amplified power.

It can be appreciated that implementing the RF PA chip with one die greatly increases integration of the chip and reduces cost of the chip.

Referring to FIG. 3(b) which shows a schematic diagram showing a physical structure of an RF front-end chip according to an embodiment of the present disclosure, a switching circuit (labeled as switching), a control logic circuit (labeled as a control logic voltage IC) and an RF PA circuit (labeled as high-frequency amplification, medium-frequency amplification and low-frequency amplification) are integrated on one die using the SOI process, and form a multi-layer and multi-module structure in terms of layout, which includes illustratively: a gate electrode polysilicon, an N-well, an active region, a P+ implant, an N+ implant, a contact hole, a first metal layer, a second metal layer, a third metal layer, a fourth metal layer, an RDL, i.e., a Redistribution Layer, a re-wiring layer, a pad windowing, etc.

The inventive RF front-end chip implements the RF signal amplification function with high integration, a small size and a compact structure, so that space of the RF module is saved for other integrated chips, and less devices are used to save costs. It can be applied to low-power consumption wide-area Internet of Things (LP-WAN) devices, 3G/4G mobile phones or other mobile handheld devices, wireless IoT modules, etc. to support a variety of standards of wireless communication.

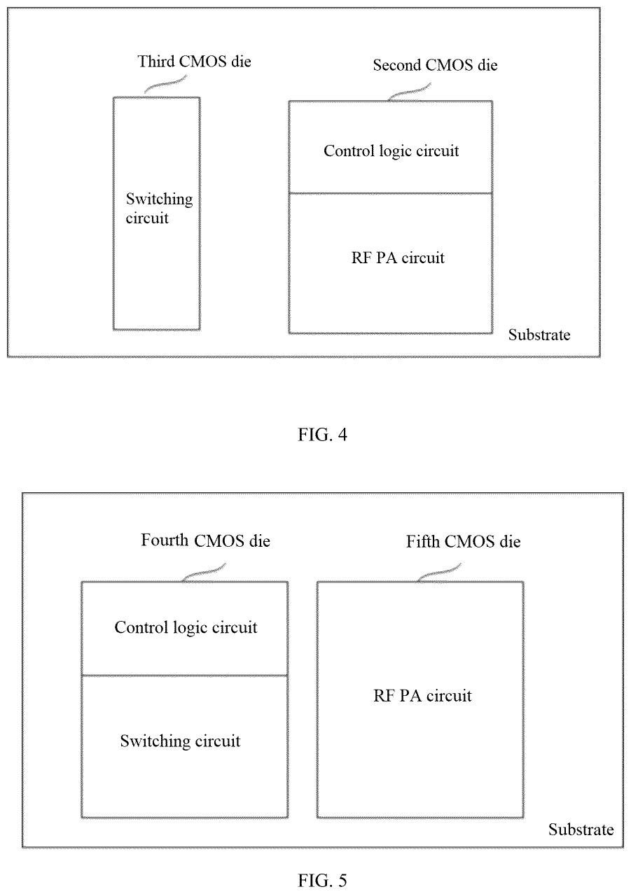

Referring to FIG. 4, in another embodiment, an RF PA chip alternatively can be implemented by using two dies including:
a second die integrating therein a control logic circuit and an RF PA circuit, as well as a MIPI circuit (not shown in the figure) and a bias circuit (not shown in the figure) for providing a bias voltage for the whole circuitry, and
a third die integrating therein a switching circuit.

In other words, the control logic circuit (CTRL) and the RF PA circuit (PA) are integrated together on the second die and the switching circuit (SW) is integrated separately on the third die. Furthermore, the second die and the third die are mounted on the same substrate based on the full SOI process.

Referring to FIG. 5, in still another embodiment, an RF PA chip is alternatively implemented by using two dies including:
a fourth die integrating therein a MIPI circuit (not shown in the figure), a bias circuit (not shown in the figure) for providing a bias voltage for the whole circuitry, a control logic circuit and a switching circuit; and a fifth die integrating therein the RF PA circuit.

In other words, the control logic circuit (CTRL) and the switching circuit (SW) are integrated together on the fourth die and the RF PA circuit (PA) is integrated separately on the fifth die. In addition, the fourth die and the fifth die are mounted on the same substrate based on the full SOI process.

It can be understood that, compared with the RF PA chip implemented by using one die, the RF PA chip implemented by using two dies has improved output isolation and a better power amplification effect.

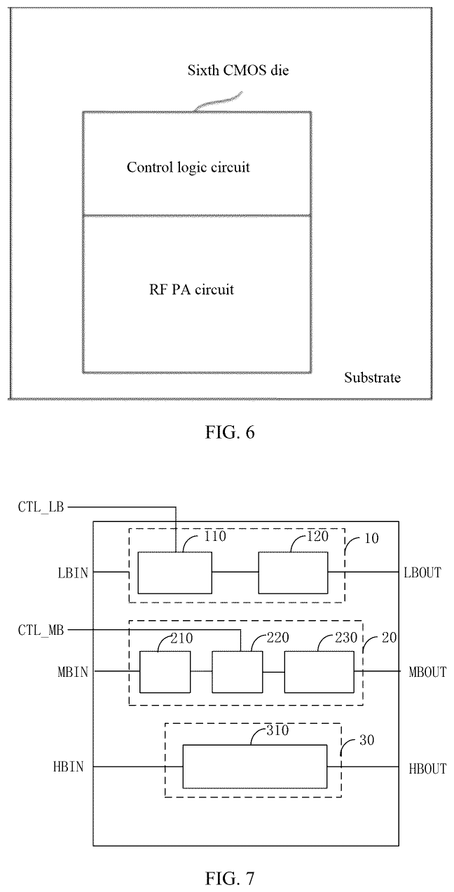

Referring to FIG. 6, in yet another embodiment, there is another way of implementing an RF PA chip by using one die in which a special RF switch circuit is not integrated, specifically the RF PA chip includes:
a sixth die integrating therein the RF PA circuit and a control logic circuit for providing logic levels to the circuitry.

In other words, the control logic circuit (CTRL) and the RF PA circuit (PA), but not the special switching circuit (SW), are integrated on one die, so that the circuitry is greatly simplified.

Further, the RF PA circuit includes an amplifier module corresponding to a predetermined frequency band, and the switching circuit includes a sub-switching circuit corresponding to the predetermined frequency band, with the sub-switching circuit being integrated to the amplifier module.

Referring to FIG. 7, the RF front-end chip provided in the embodiments of the present disclosure may be a multi-mode multi-frequency RF chip, which can support a multi-band multi-mode RF function. In this case, the RF PA circuit includes a low-frequency amplification module 10, a medium-frequency amplification module 20 and a high-frequency amplification module 30, and the switching circuit includes one or more sub-switching circuits respectively integrated on one or more of the low-frequency amplification modules 10, the medium-frequency amplification module 20 and the high-frequency amplification module 30.

For example, the low-frequency amplification module 10 includes a first switch unit 110 and a first amplifier unit 120, the medium-frequency amplification module 20 includes a primary amplification unit 210, a second switch unit 220 and a secondary amplification unit 230, and the high-frequency amplification module 30 includes a second amplifier unit 310.

With the RF PA circuit designed as above, the low-frequency amplification module 10 is configured to receive a low-frequency band RF signal LBIN, and the first switch unit 110 is configured to cause the first amplifier unit 120 to amplify the received low-frequency band RF signal LBIN or not according to the first control signal CTL_LB. For example, when the first control signal CTL_LB received by the first switch unit 110 is a high level signal, the first switch unit 110 is turned on, so that the first amplifier unit 120 amplifies the received low-frequency band RF signal LBIN and outputs the amplified low-frequency band RF signal LBOUT; when the first control signal CTL_LB received by the first switch unit 110 is a low level signal, the first switch unit 110 is turned off, so that the first amplifier unit 120 does not amplify the received low-frequency band RF signal LBIN.

The medium-frequency amplification module 10 is configured to receive a medium-frequency band RF signal MBIN, and the second switch unit 220 is configured to cause the primary amplification unit 210 and the secondary amplification unit 230 to amplify the received medium-frequency band RF signal MBIN or not according to the second control signal CTL_MB. For example, when the second control signal CTL_MB received by the second switch unit 220 is a high level signal, the second switch unit 220 is turned on, so that the primary amplification unit 210 and the secondary amplification unit 230 amplify the received medium-frequency band RF signal MBIN and output the amplified medium-frequency band RF signal MBOUT; when the second control signal CTL_MB received by the second switch unit 220 is a low level signal, the second switch unit 220 is turned off, so that the first amplification unit 210 and the second amplification unit 230 do not amplify the received medium-frequency band RF signal MBIN.

The second amplifier unit 310 in the high-frequency amplification module 30 is configured for amplifying the received high-frequency band RF signal HBIN. The low-frequency band RF signal LBIN, the medium-frequency band RF signal MBIN and the high-frequency band RF signal HBIN are all RF signals, but are different in that the frequencies of the RF signals of the low-frequency band RF signal, the medium-frequency band RF signal and the high-frequency band RF signal are different, to adapt to the transmission requirements of the different frequency bands.

In the present embodiment, a low-frequency amplification module, a medium-frequency amplification module and a high-frequency amplification module are integrated together, and a plurality of sub-switching circuits contained in a switching circuit are respectively integrated on the low-frequency, medium-frequence and high-frequency amplification modules, so that amplification of a low-frequency band RF signal is controlled by a first switch unit integrated in the low-frequency amplification module, and amplification of a medium-frequency band RF signal is controlled by a second switch unit integrated in the medium-frequency amplification module, so that RF amplification is controllable, and thus the RF front-end chip of the present embodiment can achieve amplification function of the RF signal, high integration, small size and compact structure. Therefore, the space of the RF module is saved for other integrated chips, and less devices are used to save device costs.

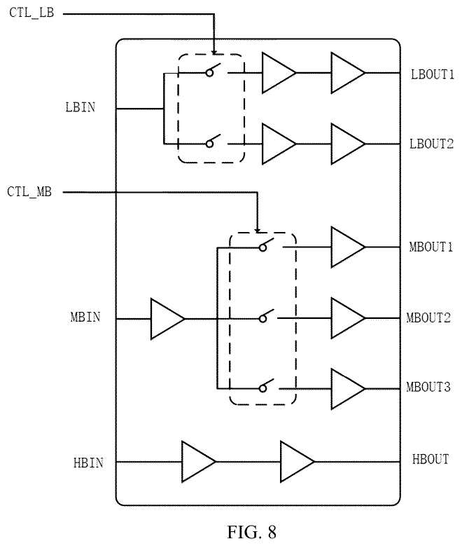

FIG. 8 shows a schematic circuit design diagram of an RF front-end chip according to one embodiment of the present disclosure. A switching circuit in the RF front-end chip is configured for processing a low-frequency signal LBIN received from a terminal under the control of a control signal CTL_LB, and includes two branches which respectively output a signal LBOUT1 and a signal LBOUT2 as output signals. Another switching circuit in the RF front-end chip is configured for processing a medium-frequency signal MBIN received from a terminal under the control of a control signal CTL_MB, and includes three branches which respectively output a signal MBOUT1, a signal MBOUT2 and a signal LBOUT3 as output signals.

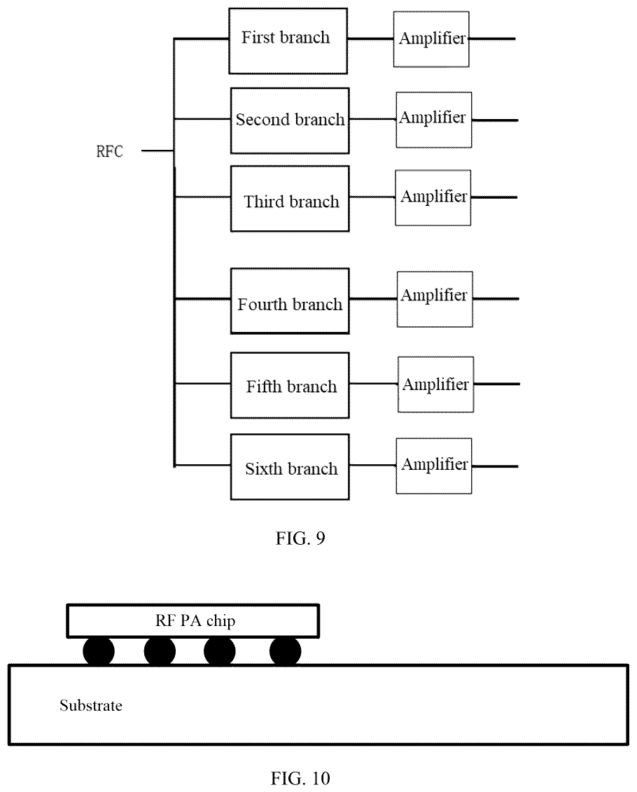

FIG. 9 shows a schematic block diagram of a switching circuit according to one embodiment of the present disclosure. The switching circuit may include a plurality of branches, particularly three or more (i.e., single pole several throw), and FIG. 9 schematically shows six branches, with an amplifier being connected downstream of each of the branches. A PA module may be provided downstream of the switching circuit.

In an embodiment, an RF PA circuit may include a low-frequency amplification module, a medium-frequency amplification module and a high-frequency amplification module, and the switching circuit may include one or more sub-switching circuits respectively integrated in the low-frequency amplification module, the medium-frequency amplification module, and the high-frequency amplification module.

In practical disclosures, a communication frequency band is roughly divided into several main frequency bands according to a frequency interval, for example, into three main frequency bands, respectively a low-frequency band, a medium-frequency band, and a high-frequency band. The range of the low-frequency band approximately ranges from 700 MHz to 1000 MHz, the medium-frequency band approximately ranges from 1700 MHz to 2200 MHz, and the high-frequency band approximately ranges from 2300 MHz to 2700 MHZ. Each main frequency band is further subdivided into a plurality of sub-frequency bands.

In an embodiment, referring to FIG. 10, an RF PA chip is packaged onto the substrate using a FC-LGA flip-chip process.

In describing the present description, reference to a description of the terms “some possible embodiments”, “some embodiments”, “examples”, “specific examples”, or “some examples”, etc. means that a particular feature, structure, material, or characteristic described in connection with the embodiment or example is included in at least one embodiment or example in the present disclosure. In the description, schematic representations of the above terms are not necessarily directed to the same embodiment or example. Furthermore, the particular features, structures, materials, or characteristics described may be combined in any suitable manner in any one or more embodiments or examples. Moreover, various embodiments or examples described in the description, as well as features of various embodiments or examples, may be integrated and combined by a person skilled in the art without departing from the scope of the present disclosure.

Based on the same technical concept, an embodiment of the present disclosure also provides a circuit structure including the RF front-end chip described in the above embodiment.

Based on the same technical concept, an embodiment of the present disclosure also provides an RF communication apparatus including the RF front-end chip described in the above embodiment.

It should be noted that the circuit structure and the RF communication apparatus in the embodiments of the present disclosure can achieve the same effects and functions as those in the embodiments of the RF front-end chip previously described, and will not be described in detail herein.

All the embodiments in the present disclosure are described in a progressive manner, and the same and similar parts among the embodiments can be referred to each other, and each embodiment focuses on the differences from other embodiments. In particular, for apparatus, device, and computer-readable storage medium embodiments, which are substantially similar to method embodiments and therefore have been described in simplified form, reference may be made to the description of the method embodiments in part to describe the same.

While the spirit and principles of the present disclosure have been described above with reference to several particular embodiments, it is to be understood that the present disclosure is not limited to the disclosed embodiments, nor is the division of aspects such that features in these aspects cannot be combined. The present disclosure is intended to cover various modifications and equivalent arrangements included within the spirit and scope of the appended claims.

What is claimed is:

1. A radio frequency (RF) front-end chip, comprising:
an RF power amplifier (PA) chip integrating therein, based on a Complementary Metal-Oxide-Semiconductor (CMOS) process, at least an RF PA circuit, and a control logic circuit, and optionally a switching circuit; and
at least one substrate, on which the RF PA chip is mounted based on a Silicon-On-Insulator (SOI) process.

2. The RF front-end chip according to claim 1, wherein the integrated RF PA circuit is configured to implement multi-stage power amplification for the RF PA chip, and is provided on the same one die as the control logic circuit or on a different die separately from the control logic circuit.

3. The RF front-end chip according to claim 2, further comprising a matching circuit comprising a circuit winding and a surface-mounted element, wherein the matching circuit is mounted on the substrate and is electrically connected to the RF PA chip to provide impedance matching.

4. The RF front-end chip according to claim 2, wherein the switching circuit is arranged at a front end of or between stages of the multi-stage power amplification of the RF PA circuit, and is configured to perform switching between amplifier modules of different frequency bands in cooperation with the control logic circuit.

5. The RF front-end chip according to claim 4, wherein the RF PA chip is implemented as a first die integrating therein the control logic circuit for supplying logic levels, the switching circuit and the RF PA circuit, wherein the RF PA chip is mounted on one substrate based on the SOI process.

6. The RF front-end chip according to claim 4, wherein the RF PA chip is implemented by:
a second die integrating therein a bias circuit for supplying a bias voltage, the control logic circuit, and the RF PA circuit; and
a third die integrating therein the switching circuit,
wherein the second die and the third die are mounted on the same substrate based on the SOI process.

7. The RF front-end chip according to claim 2, wherein the RF PA chip is implemented by:
a fourth die integrating therein the control logic circuit and the switching circuit; and
a fifth die integrating therein the RF PA circuit,
wherein the fourth die and the fifth die are mounted on the same substrate based on the SOI process.

8. The RF front-end chip according to claim 2, wherein the RF PA chip further comprises a sixth die integrating therein a control logic circuit for supplying logic levels and the RF PA circuit, wherein the sixth die is mounted on a substrate based on the SOI process.

9. The RF front-end chip according to claim 1, wherein the RF PA chip is packaged through a flip-chip land grid array (FC-LGA) process onto the substrate using the SOI process.

10. The RF front-end chip according to claim 1, wherein the RF PA circuit comprises an amplifier module corresponding to a predetermined frequency band, and the switching circuit comprises a sub-switching circuit corresponding to the predetermined frequency band, with the sub-switching circuit being integrated to the amplifier module.

11. The RF front-end chip according to claim 10, wherein the RF PA circuit comprises a low-frequency amplification module, a medium-frequency amplification module and a high-frequency amplification module, and the switching circuit comprises one or more sub-switching circuits respectively integrated to the low-frequency amplification module, the medium-frequency amplification module, and the high-frequency amplification module.

12. A method of manufacturing a radio frequency (RF) front-end chip, comprising:
preparing an RF power amplifier (PA) chip integrating therein, based on a Complementary Metal-Oxide-Semiconductor (CMOS) process, at least an RF PA circuit, and a control logic circuit, and optionally a switching circuit; and
mounting the RF PA chip on at least one substrate based on a Silicon-On-Insulator (SOI) process.

13. The method according to claim 12, wherein the integrated RF PA circuit is configured to implement multi-stage power amplification for the RF PA chip, and is provided on the same one die as the control logic circuit or on a different die separately from the control logic circuit.

14. The method according to claim 13, wherein the switching circuit is arranged at a front end of or between stages of the multi-stage power amplification of the RF PA circuit, and is configured to perform switching between amplifier modules of different frequency bands in cooperation with the control logic circuit.

15. The method according to claim 14, wherein the RF PA chip is implemented as a first die integrating therein the control logic circuit for supplying logic levels, the switching circuit and the RF PA circuit, wherein the RF PA chip is mounted on one substrate based on the SOI process.

16. The method according to claim 14, wherein the RF PA chip is implemented by:
a second die integrating therein a bias circuit for supplying a bias voltage, the control logic circuit, and the RF PA circuit; and
a third die integrating therein the switching circuit,
wherein the second die and the third die are mounted on the same substrate based on the SOI process.

17. The method according to claim 13, wherein the RF PA chip is implemented by:
a fourth die integrating therein the control logic circuit and the switching circuit; and
a fifth die integrating therein the RF PA circuit,
wherein the fourth die and the fifth die are mounted on the same substrate based on the SOI process.

18. The method according to claim 13, wherein the RF PA chip further comprises a sixth die integrating therein a control logic circuit for supplying logic levels and the RF PA circuit, wherein the sixth die is mounted on a substrate based on the SOI process.

19. A circuit structure, comprising the RF front-end chip according to claim 1.

20. A radio frequency (RF) communication apparatus, comprising the RF front-end chip according to claim 1.
